(19) United States
(12) Patent Application Publication
(10) Pub. No.: US 2009/0133806 A1
(43) Pub. Date: May 28, 2009

(54) METHOD OF MANUFACTURING DIELECTRIC SHEET AND MULTILAYER CERAMIC SUBSTRATE

(75) Inventors: Ho Sung CHOO, Suwon (KR); Soo Hyun LYOO, Yongin (KR); Myung Whun CHANG, Yongin (KR); Beom Joon CHO, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/324,964

(22) Filed: Nov. 28, 2008

(30) Foreign Application Priority Data
Nov. 28, 2007 (KR) 10-2007-0122163

(51) Int. Cl. H05K 3/10; B32B 37/06

(52) U.S. Cl. 156/89.12; 427/98.4

(57) ABSTRACT

There is provided a method of manufacturing a dielectric sheet and a multilayer ceramic substrate. A method of manufacturing a dielectric sheet according to an aspect of the invention may include: forming an embossed pattern formed of a thermoplastic material on a carrier film; forming a dielectric sheet by casting dielectric slurry onto the carrier film to cover the embossed pattern; removing the carrier film and the embossed pattern to leave an intaglio pattern having the shape corresponding to the embossed pattern on the dielectric sheet; and filling the intaglio pattern of the dielectric sheet with a conductive material.

According to an aspect of the invention, a method of manufacturing a dielectric sheet and a multilayer ceramic substrate that can prevent the generation of irregularities when a dielectric sheet having an intaglio electrode pattern printed thereon is laminated to a multilayer substrate can be provided.

### CROSS-REFERENCE TO RELATED APPLICATIONS

This application claims the priority of Korean Patent Application No. 2007-0122163 filed on Nov. 28, 2007, in the Korean Intellectual Property Office, the disclosure of which is incorporated herein by reference.

### BACKGROUND OF THE INVENTION

1. Field of the Invention

The present invention relates to methods of manufacturing dielectric sheets and multilayer ceramic substrates, and more particularly, to a method of manufacturing a dielectric sheet having an electrode printed in intaglio and a dialect sheet manufactured thereby.

2. Description of the Related Art

In general, multilayer ceramic substrates are used as components including active elements, such as semiconductor IC chips, and passive elements, such as capacitors, inductors, and resistors, which are put together, or are simply used as semiconductor IC packages. Specifically, the multilayer ceramic substrates are widely used to manufacture various kinds of electronic components, such as PA module substrates, RF diode switches, filters, chip antennas, various package components, and composite devices.

Particularly, ceramic components that operate in the high frequency band, have various functions and small size have been used in wireless communication systems. The ceramic components are generally manufactured by using a low temperature cofired ceramics (LTCC) process in which the ceramic components are fired at a low temperature on the basis of a lamination technique.

A multilayer ceramic substrate manufactured by using the LTCC process generally has a plurality of ceramic sheets laminated to one another and electrodes respectively formed on the sheets. Here, the electrodes are electrically connected to each other through via holes.

FIG. 1 is a cross-sectional view illustrating dielectric sheets laminated to each other in an LTCC process according to the related art.

As shown in FIG. 1, electrode patterns formed by embossed printing are formed on dielectric sheets 11 that constitute a ceramic laminate 100.

When the plurality of dielectric sheets 11 are laminated, the electrode patterns 12 may cause irregularities of the dielectric sheets 11. The more the dielectric sheets are laminated, the bigger the problem is.

When the irregularities cause a split between the dielectric sheets 11, a plating solution may seep between the electrode patterns 12 and the electrodes 11 during a subsequent plating process to form an external electrode. Therefore, the adhesion between the electrodes and the ceramic sheets in a finished product may be reduced to cause a reduction in product reliability.

### SUMMARY OF THE INVENTION

An aspect of the present invention provides a method of manufacturing a dielectric sheet that can prevent the generation of irregularities when a dielectric sheet having an intaglio electrode pattern printed thereon is laminated to a multilayer substrate.

Another aspect of the present invention provides a method of manufacturing a multilayer ceramic substrate including the dielectric sheet manufactured by the above manufacturing method.

According to an aspect of the present invention, there is provided a method of manufacturing a dielectric sheet, the method including: forming an embossed pattern formed of a thermoplastic material on a carrier film; forming a dielectric sheet by casting dielectric slurry onto the carrier film to cover the embossed pattern; removing the carrier film and the embossed pattern to leave an intaglio pattern having the shape corresponding to the embossed pattern on the dielectric sheet; and filling the intaglio pattern of the dielectric sheet with a conductive material.

The embossed pattern may be formed of a polymer material.

The embossed pattern may be formed of a material selected from the group consisting of polyethylene (PE), polypropylene (PP), polyethylene terephthalate (PET), polyvinyl chloride (PVC), and cellulose.

The carrier film and the embossed pattern may be formed of the same material.

The method may further include applying a release agent onto the embossed pattern before forming the dielectric sheet.

The release agent may be formed of a silicon-based material or a fluorine-based material.

The forming the embossed pattern may be performed by a method selected from the group consisting of screen printing, gravure printing, and inkjet printing.

The forming the dielectric sheet may include drying the dielectric slurry after casting the dielectric slurry.

The conductive material may be formed of at least one material selected from the group consisting of Ag, Cu, and Ni.

According to another aspect of the present invention, there is provided a method of manufacturing a multilayer ceramic substrate, the method including: preparing a dielectric laminated structure including at least one dielectric sheet manufactured by the method of any one of claims 1 through 9, and a conductive via providing an interlayer electrical connection; and firing the dielectric laminated structure at a firing temperature of the dielectric sheet.

The multilayer ceramic substrate may be a low temperature cofired ceramic substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating dielectric sheets laminated in an LTCC process according to the related art;

FIGS. 2A through 2D are cross-sectional views illustrating a process of manufacturing a dielectric sheet according to an exemplary embodiment of the present invention;

FIG. 3 is a cross-sectional view illustrating a part of a method of manufacturing a dielectric sheet according to another exemplary embodiment of the present invention; and

FIG. 4 is a cross-sectional view illustrating a multilayer ceramic substrate according to an exemplary embodiment of the present invention.

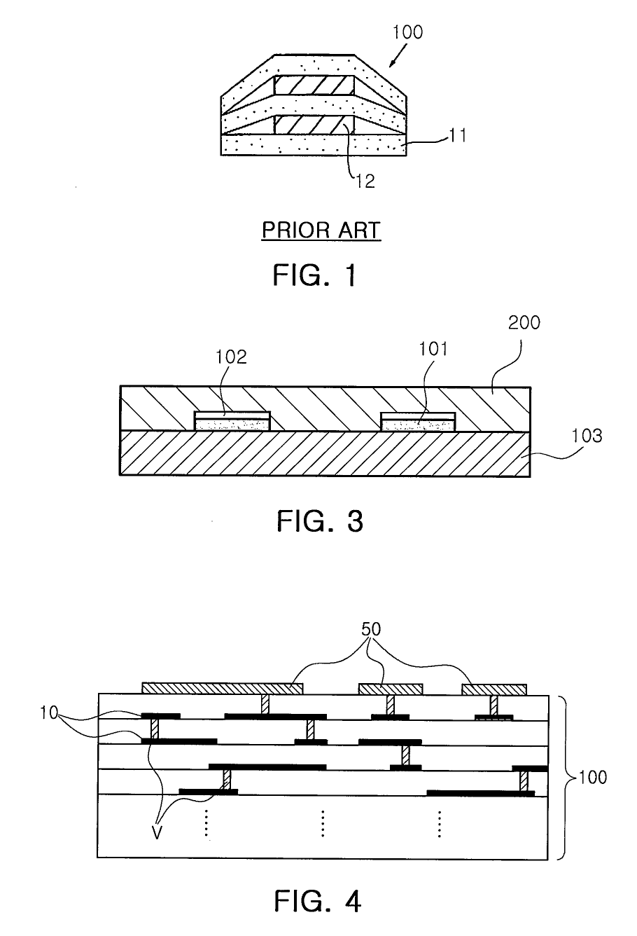

### DETAILED DESCRIPTION OF THE PREFERRED EMBODIMENT

Exemplary embodiments of the present invention will now be described in detail with reference to the accompanying drawings.

The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

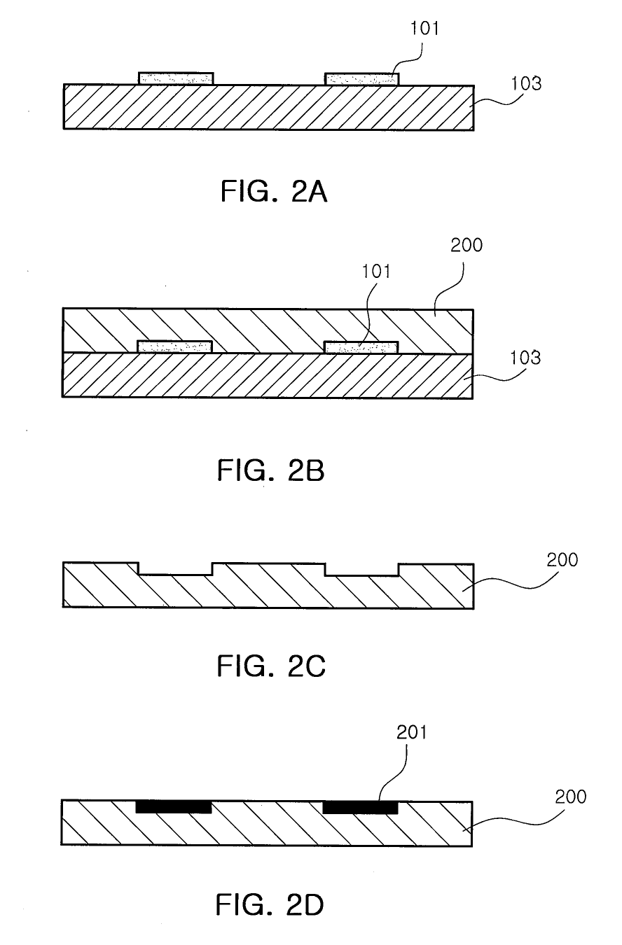

FIG. 2A through 2D are cross-sectional views illustrating a process of manufacturing a dielectric sheet according to an exemplary embodiment of the invention.

As shown in FIG. 2A, a predetermined embossed pattern 101 is formed on a carrier film 103.

The carrier film 103 may be formed of synthetic resin. For example, a PET film may be preferably used.

The embossed pattern 101 is provided to form an intaglio pattern on the dielectric sheet, which will be described below. Here, the embossed pattern 101 has a shape corresponding to the position and size of an intaglio electrode pattern to be mounted into the dielectric sheet. The embossed pattern 101 may be formed by using screen printing, gravure printing, inkjet printing, and the like.

Preferably, the embossed pattern 101 is formed of a thermoplastic material whose thermal expansion coefficient is not much different from a material forming the carrier film 103.

Therefore, the embossed pattern 101 may be formed of a polymer material, such as synthetic resin. Specifically, examples of the material forming the embossed pattern 101 may include polyethylene (PE), polypropylene (PP), polyethylene terephthalate (PET), polyvinyl chloride (PVC), and cellulose. Particularly, in consideration of the process convenience, when the embossed pattern 101 is formed of the same material as the carrier film 103, the embossed pattern 101 is preferably formed of, for example, a PET film.

Then, as shown in FIG. 2B, dielectric slurry is cast onto the carrier film 103 to form a dielectric sheet 200. Here, the dielectric slurry is provided to cover the embossed pattern 101 so that the intaglio pattern corresponding to the embossed pattern 101 is formed on the dielectric sheet 200.

The dielectric slurry is a mixture of glass, a binder, and a ceramic filler that are mixed at a predetermined ratio. The dielectric slurry is dispensed onto the carrier film 103, and then dried to manufacture the dielectric sheet 200. The process of casting the dielectric slurry can be performed by using a known doctor blade process. A detailed description thereof will be omitted.

Then, as shown in FIG. 2C, the embossed pattern 101 and the carrier film 103 are removed from the dielectric sheet 200. The intaglio pattern is formed on the dielectric sheet 200 by using the embossed pattern 101 and the carrier film 103. The intaglio pattern is provided as a region to be filled with a conductive material for an electrode.

Here, the embossed pattern 101 and the carrier film 103 can be easily removed by using a physical or chemical method. Considering the fact that the embossed pattern 101 and the carrier film 103 are preferably formed of materials similar with the dielectric sheet 200, the physical method is preferred to the chemical method. If a release agent is applied to the embossed pattern 101 beforehand, the embossed pattern 101 and the carrier film 103 can be more easily removed, which will be described below with reference to FIG. 3.

Finally, as shown in FIG. 2D, a conductive material, such as Ag, Cu, and Ni, fills the intaglio pattern of the dielectric sheet 200 to thereby form an electrode pattern 201 that is intaglio engraved. The electrode pattern 201 may be formed by using known processes. As a representative example among the known processes, a paste with Ag powder is applied onto the intaglio pattern by screen printing.

As described above, as compared to when an electrode is formed by embossed printing, the dielectric sheet 200 having the electrode pattern 201 printed in intaglio according to this embodiment can prevent the generation of irregularities during lamination. Therefore, improvements in reliability of the multilayer ceramic substrate can be expected.

Particularly, when the intaglio electrode pattern is formed, the carrier film and the embossed pattern are formed of the same or similar material to each other, thereby reducing a difference in change between the carrier film and the electrode pattern caused by heat during the process. Therefore, improvements in stability and reliability can be achieved when designing the electrode pattern.

FIG. 3 is a cross-sectional view illustrating a part of a method of manufacturing a dielectric sheet according to another exemplary embodiment of the invention.

The process, shown in FIG. 3, is performed between the processes of FIGS. 2A and 2B in the embodiment illustrated in FIGS. 2A through 2D. A process of applying a release agent 102 onto an embossed pattern 101 in advance in order to more easily remove a carrier film 103 and the embossed pattern 101 is further included.

The release agent 102 is previously applied onto the embossed pattern 101 before casting dielectric slurry so that the carrier film 103 and the embossed pattern 101 can be removed. The release agent 102 may be formed of a silicon-based material and a fluorine-based material.

FIG. 4 is a cross-sectional view illustrating a multilayer ceramic substrate according to an exemplary embodiment of the invention.

A multilayer ceramic substrate according to this embodiment includes a laminated structure 100 having electrodes 10 and conductive vias V, and external electrodes 50 formed on one surface of the laminated structure 100. The laminated structure 100 is formed by laminating a plurality of dielectric sheets having the internal electrode 10 printed in intaglio. The multilayer ceramic substrate may be manufactured using a low temperature cofired ceramics (LTCC) process. The multilayer ceramic substrate may be obtained by firing the laminated structure 100 at a predetermined temperature.

Further, since the multilayer ceramic substrate includes the dielectric sheets, manufactured by the process, shown in FIG. 2 or 3, the generation of irregularities that may be caused with an increasing number of dielectric sheets laminated can be prevented. Therefore, the seepage of the plating solution between the dielectric sheet and the electrode pattern in the related art can be prevented, which contributes to improvements in reliability of a finished product.

As set forth above, according to exemplary embodiments of the invention, a method of manufacturing a dielectric sheet and a multilayer ceramic substrate that can prevent the generation of irregularities when a dielectric sheet having an intaglio electrode pattern printed thereon is laminated to a multilayer substrate can be provided.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a dielectric sheet, the method comprising:
forming an embossed pattern formed of a thermoplastic material on a carrier film;
forming a dielectric sheet by casting dielectric slurry onto the carrier film to cover the embossed pattern;
removing the carrier film and the embossed pattern to leave an intaglio pattern having the shape corresponding to the embossed pattern on the dielectric sheet; and
filling the intaglio pattern of the dielectric sheet with a conductive material.

2. The method of claim 1, wherein the embossed pattern is formed of a polymer material.

3. The method of claim 1, wherein the embossed pattern is formed of a material selected from the group consisting of polyethylene (PE), polypropylene (PP), polyethylene terephthalate (PET), polyvinyl chloride (PVC), and cellulose.

4. The method of claim 1, wherein the carrier film and the embossed pattern are formed of the same material.

5. The method of claim 1, further comprising applying a release agent onto the embossed pattern before forming the dielectric sheet.

6. The method of claim 5, wherein the release agent is formed of a silicon-based material or a fluorine-based material.

7. The method of claim 1, wherein the forming the embossed pattern is performed by a method selected from the group consisting of screen printing, gravure printing, and inkjet printing.

8. The method of claim 1, wherein the forming the dielectric sheet comprises drying the dielectric slurry after casting the dielectric slurry.

9. The method of claim 1, wherein the conductive material is formed of at least one material selected from the group consisting of Ag, Cu, and Ni.

10. A method of manufacturing a multilayer ceramic substrate, the method comprising:
preparing a dielectric laminated structure including at least one dielectric sheet manufactured by the method of claim 1, and a conductive via providing an interlayer electrical connection; and
firing the dielectric laminated structure at a firing temperature of the dielectric sheet.

11. The method of claim 10, wherein the multilayer ceramic substrate is a low temperature cofired ceramic substrate.
